(19) United States
(12) Patent Application Publication
(10) Pub. No.: US 2010/0073871 A1
(43) Pub. Date: Mar. 25, 2010

(54) EFFICIENT SITE COOLING TECHNOLOGY

(76) Inventor: Michael Patrick Flynn, Rancho Santa Fe, CA (US)

Correspondence Address: LEWIS, BRISBOIS, BISGAARD & SMITH LLP, 221 NORTH FIGUEROA STREET, SUITE 1200, LOS ANGELES, CA, 90012, US

(21) Appl. No.: 12/566,527

(22) Filed: Sep. 24, 2009

Related U.S. Application Data
(60) Provisional application No. 61/099,772, filed on Sep. 24, 2008.

(51) Int. Cl. H05K 7/20; H02J 9/00

(52) U.S. Cl. 361/689; 361/688; 307/64

(57) ABSTRACT

A method for providing Electronic Equipment cabinets and shelters with an advanced supplemental cooling system, with the use of “stored coolant” produced during off peak periods as opposed to the use of peak rate power for a typical air conditioner unit, the ability to operate the electronic equipment during periods when primary power is lost and the on-site back up power plant is not sufficient to operate both the electronics and the cooling system, as well as the ability to save the operators money, by load shifting power usage from peak to off peak hours, often at lower utility rates and use alternative green technologies for power, such as wind and solar.

This application claims the benefit of U.S. Provisional Application Ser. No. 61/099,772, filed Sep. 24, 2008, which application is incorporated herein by reference in its entirety.

### FIELD OF THE INVENTION

This application involves the ability to supplement or replace typical air conditioner technology on cell sites, and other electronic equipment installations, with a Stored Cooling Technology, improving power usage and cell site availability.

This invention is a method of improving the efficiency of electronic equipment cooling, enhancing the ability to run electronic equipment on back up power and allow for “load shifting” from peak to off peak electric utility rates by using power at night—off peak to create a stored cooling mechanism, such as ice or a chemical coolant, that can be used to cool the electronic equipment during daylight peak periods. This includes electronic equipment at cell sites and other locations where electronic equipment is housed in outdoor cabinets and shelters. Electronic equipment can be transmitters/receivers and associated electronics, power supply cabinets with back up power equipment, from power supplies to batteries and other components.

### BACKGROUND OF THE INVENTION

Cell sites and other users of electronic equipment housed in outdoor cabinets and/or shelters are located at or near the base of telecommunications towers. Each cell site can have a plurality of individual outdoor cabinets and/or a larger shelter which houses a number of indoor electronic equipment cabinets and other associated electronics and/or back up power equipment.

A cell site is located in various geographic locations and in almost all cases involves the connection to a primary power source, as well as some form of back up power, which can include batteries, fuel cells and/or generators to power the electronics used to broadcast the operators' spectrum at each cell site when the primary power, electric utility's power supply, is interrupted due to black outs, natural disasters and the like.

### SUMMARY OF THE INVENTION

The present invention provides an improved system for cooling the Electronic Equipment at the cell site. Today, back up power in the event that standard commercial power is interrupted at a site is mostly provided by battery back up and/or fuel cell, with a smaller number of cell sites using back up generators. The invention comprises the use of a supplemental cooling system comprising Stored Cooling in the form of ice, chemical coolant, or other means, to allow the cooling system to create cooling during off-peak utility rates compared to peak rate utility rates. This creates a number of advantages over the typical Electronic Equipment Cabinet system which uses a typical air conditioner unit. Applicant's Cooling System allows the incorporation of a Stored Cooling system into one or more or each of the outdoor Cabinets and/or Shelters located at each cell site, or users of other Electronic Cabinets for providing various other services. This is accomplished by incorporating a Stored Cooling system into the door of each of the outdoor Electronic Equipment Cabinets and incorporating a Stored Cooling system into a wall mounted unit for placement on the sides of shelters, where the typical air conditioners are located today.

The applicant's Stored Cooling system is a unit that integrates the Stored Cooling system and a typical/standard air conditioner into a combined cooling system. The use of the typical/standard air conditioner occurs when the Stored Cooling system reserve of “frozen/coolant” has been exhausted and/or if the Stored Cooling system has been programmed to always maintain a set amount of stored coolant reserve, such as 8 hours. The typical/standard air conditioner is always available when commercial power is available to back up the Stored Cooling system, if it fails, and can also run on a cell site generator and/or fuel cell (battery in some cases if the battery plant is excessively large, not the case on most, cell sites) if those back up power plants are sufficient in size/power output.

The Stored Cooling system incorporated into the doors of outdoor cabinets allows the new technology to be placed on existing deployed outdoor cabinets with a simple replacement of the existing air conditioner with the new Stored Cooling system unit and/or for a new door, in the same form as the existing cabinet door, with the Stored Cooling system to be used to swap out the old door and existing cooling system with the new door with the Stored Cooling system incorporated. This method allows for the operators to avoid placing new cabinets/equipment and to use the existing lease space of the already deployed outdoor cabinets.

The Stored Cooling system can also be incorporated into the manufacturing/offering of OEM developed equipment, cabinets and shelters sold up front to the operators.

In the shelter opportunity, the new Stored Cooling system uses the same “cut outs” that exist in the already deployed shelters to avoid having to modify the shelters, as well as on new shelters manufactured by the OEM.s. The placement of the Stored Cooling system on shelters also eliminates the need for the operators to have to lease additional ground space.

The offering of a fully integrated Electronic Cabinet with the Stored Cooling system allows for the operators to purchase electronic equipment cabinets that have the Stored Cooling system fully incorporated into the cabinet offering.

The ability to not increase the operators use of additional lease area is a tremendous advantage over having to use already leased valuable lease space at the cell site, which can be used for other electronic equipment and/or avoid having to pay the land owner and/or tower operators additional rent. The payment of additional rent is a large operational expense that the operators always want to avoid and have a negative impact on the operators' decision to deploy any new technology, since operational expense minimization is always a priority.

One of the advantages/Options of Applicant's invention is that the size of the operators' back up power plant; battery, fuel cell and/or generator infrastructure/equipment can be smaller. This is accomplished due to the Stored Cooling system using a fraction of the power required to operate a typical air conditioner unit. In a typical air conditioner unit, the compressor and other components require substantial power each time the unit starts up.

With the Stored Cooling system, the “coolant—ice or other means” is made at night during the off peak utility rate and is accomplished with the use of a steady draw of electricity when making the stored cooling and also when used to cool the Electronic Equipment during the peak period. In addition, the power draw used during the peak cooling period is substantially lower than the typical air conditioner by a magnitude.

This also provides a key benefit to the invention, which is the ability to operate the Electronic Equipment when off of peak commercial power, a power outage. The Stored Cooling system allows the equipments' back up power plant, especially when batteries and/or fuel cells are used, to fully operate the complete Electronic Equipment cabinet and/or shelter. Today, if a loss of power occurs, the battery and/or fuel cell plant usually cannot operate the cabinets and/or shelters typical air conditioners, only the other electronic equipment, such as the transmitters and receivers and other broadcast equipment. The problem with the current cabinet and/or shelter with a typical air conditioner is, that due to the typical air conditioners need for substantial power, the cabinets and/or shelters can't run the integrated cooling system. Thus, if a cell site looses commercial power, the cooling systems don't operate and the electronic equipment overheats, which in turn shuts off the electronic equipment and the cell site goes off air. This invention eliminates that from happening.

The use of the Stored Cooling system also provides the operators a more efficient use of electricity with the ability to load shift their power usage from peak to off peak.

The use of the Stored Cooling system also reduces the environmental impact of the electronic equipment and the operator on the environment by operating more efficiently and using off peak electricity, which is produced more efficiently and cleanly than peak electricity production by the electric utilities.

The Stored Cooling system can also have programmable control logic to allow various configurations of how the Stored Cooling is used and produced. An example of this would the making of the stored cooling mechanism in sufficient volume to guarantee a minimum availability, such as 8 hours as proposed by the FCC (note that today, even if the operators take the position they have an 8 hour back up plant—battery/fuel cell, in fact they do not truly have a back up plant that will keep the cell site operational for 8 hours, since they can't cool the electronic equipment, which results in the cell site going off air) and an amount of stored cooling to also operate during peak time as well.

The Stored Cooling system also allows additional uses of alternative electricity production, such as wind power, solar and other green technologies based on its relatively steady power draws during the coolant making period and operation.

Another option is the use of an outdoor electronic cabinet which has the stored coolant either in the door infrastructure as described above and/or incorporating other portions of the outdoor cabinet and/or shelter to house the stored coolant, such as in a separate sub base and/or plinth or integrated storage compartment within the cabinet and/or shelter.

### BRIEF DESCRIPTIONS OF THE DRAWINGS

FIG. 1 is a depiction of the operation of a cell site with and without the Stored Cooling system.

FIG. 2 is a depiction of a Cabinet with the Stored Cooling located within a Plinth/Sub Base (separate unit and/or fully integrated into the cabinet), within a cabinet door and/or within a new cabinet door.

FIG. 3 is a depiction of a Shelter with the Stored Cooling located separately from the shelter and/or within the shelter and/or with the location on the side of the shelter.

FIG. 4 is a depiction of a cabinet with the integrated Stored Cooling system, which can be located in the door and/or the sub base and/or plinth.

FIG. 5 is a depiction of the Stored Cooling system along with other “green technologies”, such as Wind Energy, to make the Stored Cooling system even more efficient and green.

### DETAILED DESCRIPTION OF THE INVENTION

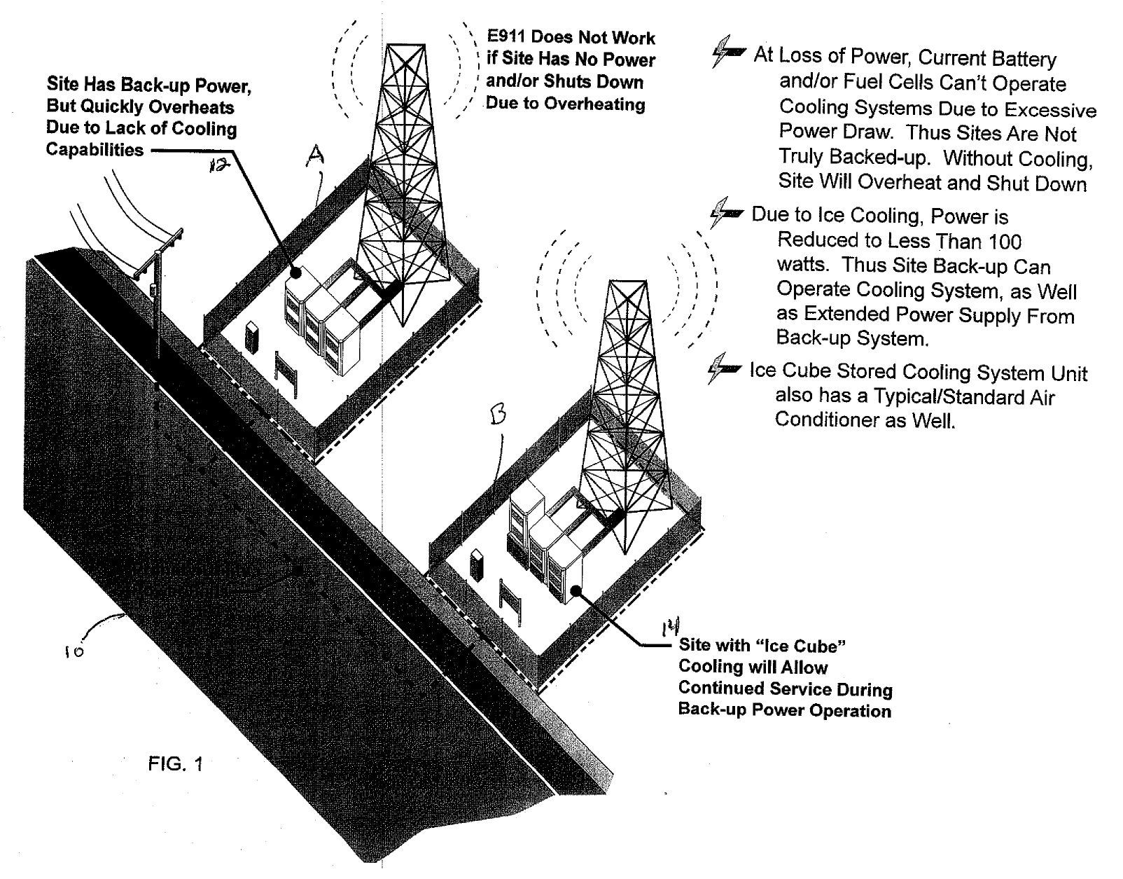

Referring to the drawings, FIG. 1 shows a Cell Site A which includes a Primary Utility Provider 10. If power fails, the site has back-up power 12 but the site quickly overheats due to lack of cooling capabilities. Emergency 911 does not work if the site has no power and shuts 160 down due to overheating.

Cell site B however has “ice cube” cooling 14 which will allow continued service during back-up power operation. At loss of power, as in cell site A, current battery and/or fuel cells cannot operate the cooling systems due to excessive power draw. Thus, the site is not truly backed-up. Without cooling, the site will overheat and shut down. With ice cooling, power is reduced to less than 100 watts. Thus, the site back-up can operate the cooling system as well as extended power supply from the back-up system. The “ice cube” cooling system unit can also have a standard typical air conditioner.

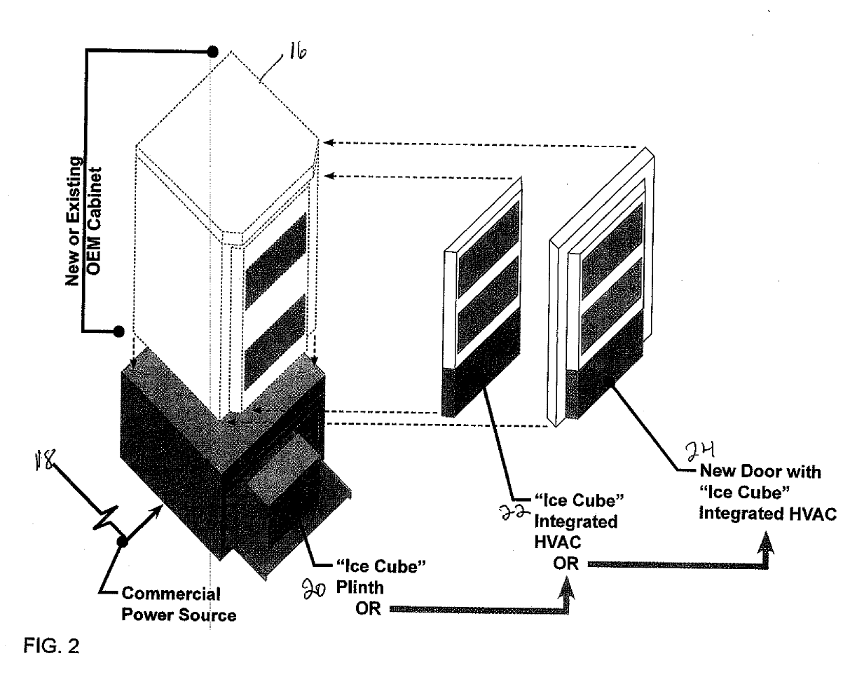

FIG. 2 shows a new or existing OEM electronics cabinet 16 run by a commercial power source 18. Added to the cabinet can be an “ice cube” plinth 20, an “ice cube” integrated HVAC 22, or a new door with an “ice cube” integrated HVAC.

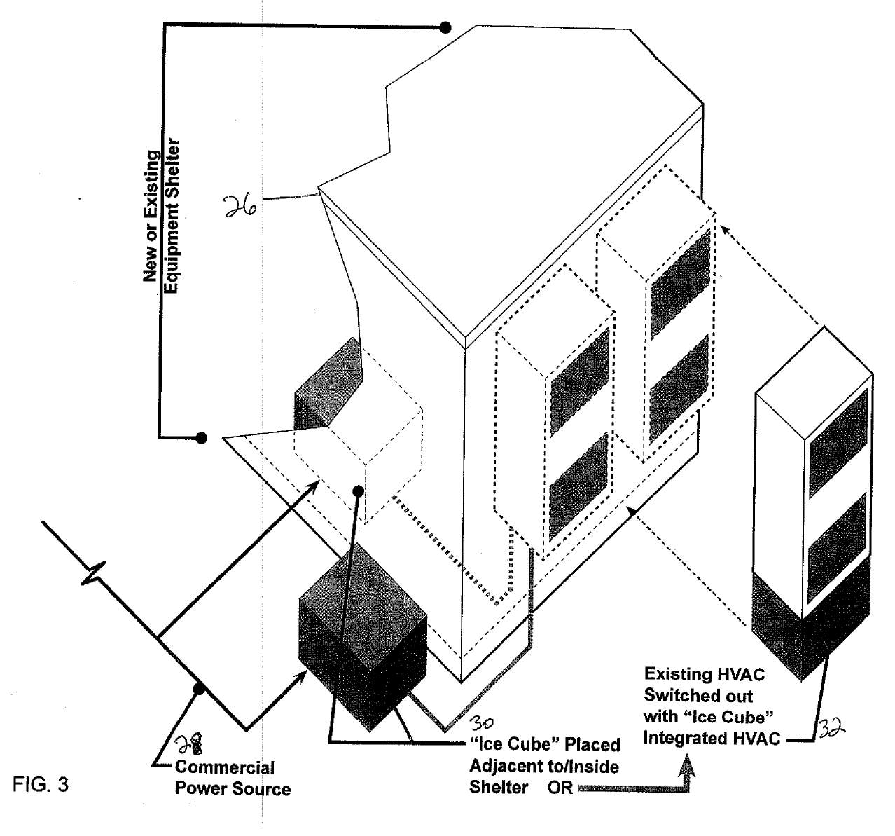

FIG. 3 shows a new or existing equipment shelter 26 run by a commercial power source 28. An “ice cube” system 30 is placed adjacent to or inside shelter 26 or the existing HVAC system is switched out and replaced with an “ice cube” integrated HVAC 32.

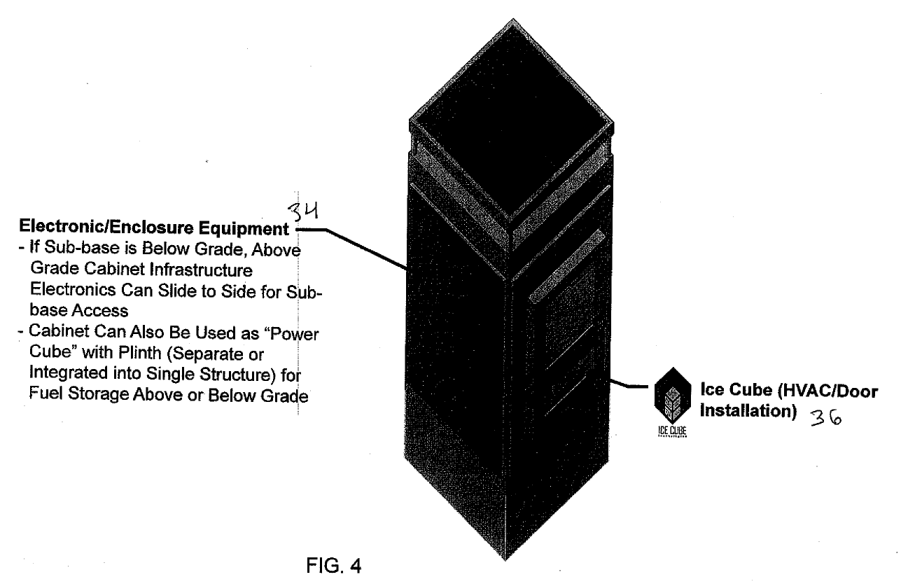

FIG. 4 shows an electronic equipment enclosure 34 with an “ice cube” HVAC door installation 36. If the enclosure 34 sub-base is below grade, above grade cabinet infrastructure electronics can slide to the side for sub-base access. Cabinet 34 can also be used as a “power cube” with a plinth, separate or integrated into a single structure, for fuel storage above or below grade.

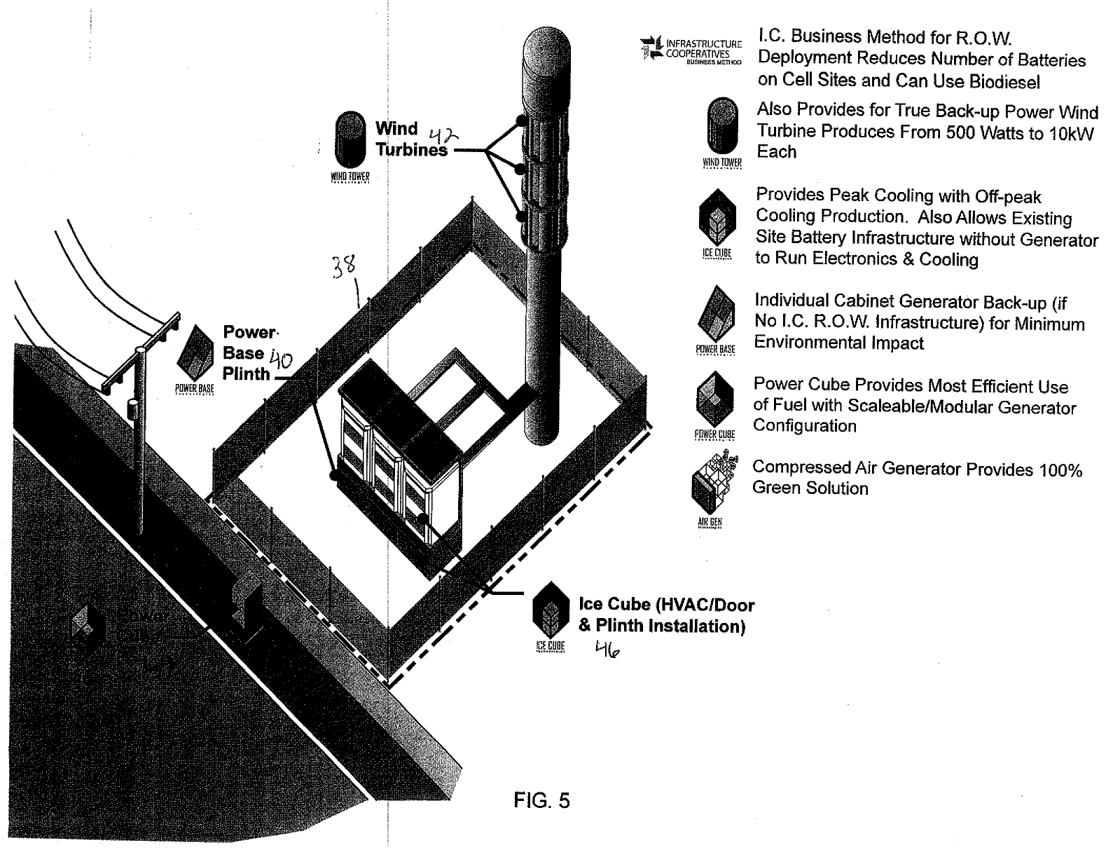

FIG. 5 shows cell site having a power base plinth 40, wind turbines 42 to provide power, a power cube 44 to provide additional power and an “ice cube” HVAC door and plinth 46 installation. Right of way deployment of back-up power generators reduces the number of batteries on cell sites and can use bio-diesel. This set-up also provides for true back up power wind turbines which can produce from 500 watts to 10 k watts each. The “ice cube” cooling system provides peak cooling with off-peak cooling production. This also allows existing site battery infrastructure for minimum environmental impact. Individual cabinet generator back-up systems can be used if no right of way infrastructure is available. The power cube 44 provides the most efficient use of fuel with scaleable generator configuration. A compressed air generator can provide a 100% green solution.

Having described the invention, I claim:

1. An electronic equipment installation comprising electronic equipment, a primary power source, back up power sources in the event primary power is lost, and a primary cooling system for the electronic equipment, further comprising a supplemental cooling system adapted to create and store cooling which is generated during off-peak utility hours.

2. The electronic equipment installation of claim 1 wherein the stored cooling is ice or a chemical coolant.

3. The electronic equipment installation of claim 1 wherein the electronic equipment is located in an indoor or outdoor cabinet.

4. The electronic equipment installation of claim 1 wherein the supplemental cooling system is located on a plinth under one or more cabinets.

5. The electronic equipment installation of claim 1 wherein the supplemental cooling system is located adjacent one or more cabinets.

6. The electronic equipment installation of claim 1 wherein the supplemental cooling system is located in the door of one or more cabinets.

7. The electronic equipment installation of claim 1 wherein the supplemental cooling system is integrated with the primary cooling system.
